(19) United States
(12) Patent Application Publication
(10) Pub. No.: US 2010/0289125 A1
(43) Pub. Date: Nov. 18, 2010

(54) ENHANCED ELECTROMIGRATION PERFORMANCE OF COPPER LINES IN METALLIZATION SYSTEMS OF SEMICONDUCTOR DEVICES BY SURFACE ALLOYING

(76) Inventors: Frank Feustel, Dresden (DE); Tobias Letz, Dresden (DE); Axel Preusse, Radebeul (DE)

Correspondence Address: WILLIAMS, MORGAN & AMERSON, 10333 RICHMOND, SUITE 1100, HOUSTON, TX, 77042, US

(21) Appl. No.: 12/769,124

(22) Filed: Apr. 28, 2010

(30) Foreign Application Priority Data
May 15, 2009 (DE) 10 2009 021 488.7

(51) Int. Cl. H01L 23/48; H01L 21/441

(52) U.S. Cl. 257/632; 438/585; 257/E21.477; 257/E23.01

(57) ABSTRACT

In sophisticated semiconductor devices, the electromigration performance of copper metal lines at the top interface thereof may be enhanced by forming a copper alloy that is locally restricted to the interface. To this end, an appropriate alloy-forming species, such as aluminum, may be provided on the basis of a non-masked deposition process and may be subsequently removed by a non-masked etch process, wherein the characteristic of the resulting alloy may be adjusted during an intermediate heat treatment.

### BACKGROUND OF THE INVENTION

1. Field of the Invention

Generally, the present disclosure relates to microstructures, such as advanced integrated circuits, and, more particularly, to the formation of conductive structures, such as copper-based metal lines, having enhanced performance with respect to electromigration.

2. Description of the Related Art

In the fabrication of modern microstructures, such as integrated circuits, there is a continuous drive to steadily reduce the feature sizes of microstructure elements, thereby enhancing the functionality of these structures. For instance, in modern integrated circuits, minimum feature sizes, such as the channel length of field effect transistors, have reached the deep sub-micron range, thereby increasing performance of these circuits in terms of speed and/or power consumption and/or diversity of functions. As the size of individual circuit elements is reduced with every new circuit generation, thereby improving, for example, the switching speed of the transistor elements, the available floor space for interconnect lines electrically connecting the individual circuit elements is also decreased. Consequently, the dimensions of these interconnect lines are also reduced to compensate for a reduced amount of available floor space and for an increased number of circuit elements provided per unit die area as typically the number of interconnections required increases more rapidly than the number of circuit elements. Thus, usually, a plurality of stacked “wiring” layers, also referred to as metallization layers, is provided, wherein individual metal lines of one metallization layer are connected to individual metal lines of an overlying or underlying metallization layer by so-called vias. Despite the provision of a plurality of metallization layers, reduced dimensions of the interconnect lines are necessary to comply with the enormous complexity of, for instance, modern CPUs, GPUs, memory chips, ASICs (application specific ICs) and the like. The reduced cross-sectional area of the interconnect structures, possibly in combination with an increase of the static power consumption of extremely scaled transistor elements, may result in considerable current densities in the metal lines, which may even increase with every new device generation.

Advanced integrated circuits, including transistor elements having a critical dimension of 0.05 μm and even less, may, therefore, typically be operated at significantly increased current densities of up to several kA per cm² in the individual interconnect structures, despite the provision of a relatively large number of metallization layers, owing to the significant number of circuit elements per unit area. Operating the interconnect structures at elevated current densities, however, may entail a plurality of problems related to stress-induced line degradation, which may finally lead to a premature failure of the integrated circuit. One prominent phenomenon in this respect is the current-induced material transport in metal lines and vias, also referred to as “electromigration.” Electromigration is caused by momentum transfer of electrons to the ion cores, resulting in a net momentum transferred to the ion cores in the direction of electron flow. In particular, at high current densities, a significant collective motion or directed diffusion of atoms may occur in the interconnect metal, wherein the presence of diffusion paths may have a substantial influence on the displaced amount of matter resulting from the momentum transfer. Thus, electromigration may lead to the formation of voids within and hillocks next to the metal interconnect, thereby resulting in reduced performance and reliability or complete failure of the device. For instance, aluminum lines embedded into silicon dioxide and/or silicon nitride are frequently used as metal for metallization layers, wherein, as explained above, advanced integrated circuits having critical dimensions of 0.1 μm or less may require significantly reduced cross-sectional areas of the metal lines and, thus, increased current densities, which may render aluminum less attractive for the formation of metallization layers.

Consequently, aluminum is being replaced by copper and copper alloys, a material with significantly lower electrical resistivity and improved resistance to electromigration even at considerably higher current densities compared to aluminum. The introduction of copper into the fabrication of microstructures and integrated circuits comes along with a plurality of severe problems residing in copper's characteristic to readily diffuse in silicon dioxide and a plurality of low-k dielectric materials, which are typically used in combination with copper in order to reduce the parasitic capacitance within complex metallization layers. In order to provide the necessary adhesion and to avoid the undesired diffusion of copper atoms into sensitive device regions, it is, therefore, usually necessary to provide a barrier layer between the copper and the dielectric material in which the copper-based interconnect structures are embedded. Although silicon nitride is a dielectric material that effectively prevents the diffusion of copper atoms, selecting silicon nitride as an interlayer dielectric material is less than desirable, since silicon nitride exhibits a moderately high permittivity, thereby increasing the parasitic capacitance of neighboring copper lines, which may result in non-tolerable signal propagation delays. Hence, a thin conductive barrier layer that also imparts the required mechanical stability to the copper is usually formed to separate the bulk copper from the surrounding dielectric material, thereby reducing copper diffusion into the dielectric materials and also reducing the diffusion of unwanted species, such as oxygen, fluorine and the like, into the copper. Furthermore, the conductive barrier layers may also form highly stable interfaces with the copper, thereby reducing the probability for a pronounced material diffusion at the interface, which is typically a critical region in view of current-induced material diffusion. Currently, tantalum, titanium, tungsten and their compounds, with nitrogen and silicon and the like, are preferred candidates for a conductive barrier layer, wherein the barrier layer may comprise two or more sub-layers of different composition so as to meet the requirements in terms of diffusion suppressing and adhesion properties.

Another characteristic of copper significantly distinguishing it from aluminum is the fact that copper may not be readily deposited in larger amounts by chemical and physical vapor deposition techniques, in addition to the fact that copper may not be efficiently patterned by anisotropic dry etch processes, thereby requiring a process strategy that is commonly referred to as the damascene or inlaid technique. In the damascene process, first a dielectric layer is formed which is then patterned to include trenches and/or vias which are subsequently filled with copper, wherein, as previously noted, prior to filling in the copper, a conductive barrier layer is formed on sidewalls of the trenches and vias. The deposition of the bulk copper material into the trenches and vias is usually accomplished by wet chemical deposition processes, such as electroplating and electroless plating, thereby requiring the reliable filling of vias with an aspect ratio of 5 and more with a diameter of 0.3 μm or even less, in combination with trenches having a width ranging from 0.1 μm to several μm. Electrochemical deposition processes for copper are well established in the field of electronic circuit board fabrication. However, for the dimensions of the metal regions in semiconductor devices, the void-free filling of high aspect ratio vias is an extremely complex and challenging task, wherein the characteristics of the finally obtained copper-based interconnect structure significantly depend on process parameters, materials and geometry of the structure of interest. Since the geometry of interconnect structures is substantially determined by the design requirements and may, therefore, not be significantly altered for a given microstructure, it is of great importance to estimate and control the impact of materials, such as conductive and non-conductive barrier layers, of the copper microstructure and their mutual interaction on the characteristics of the interconnect structure so as to insure both high yield and the required product reliability. In particular, it is important to identify, monitor and reduce degradation and failure mechanisms in interconnect structures for various configurations to maintain device reliability for every new device generation or technology node.

Accordingly, a great deal of effort has been made in investigating the degradation of copper interconnects, especially in combination with low-k dielectric materials having a relative permittivity of 3.1 or even less, in order to find new materials and process strategies for forming copper-based lines and vias with a low overall permittivity. Although the exact mechanism of electromigration in copper lines is still not quite fully understood, it turns out that voids positioned in and on sidewalls and especially at interfaces to neighboring materials may have a significant impact on the finally achieved performance and reliability of the interconnects.

One failure mechanism which is believed to significantly contribute to a premature device failure is the electromigration-induced material transport, particularly along an interface formed between the copper and an overlying metallization layer. For example, a dielectric cap layer may be formed on the copper line surface in order to maintain copper integrity. Moreover, the dielectric cap layer may usually act as an etch stop layer during the formation of the via openings in the interlayer dielectric. Frequently used materials are, for example, silicon nitride and nitrogen-containing silicon carbide, which exhibit a moderately high etch selectivity to typically employed interlayer dielectrics, such as a plurality of low-k dielectric materials, and also suppress the diffusion of copper onto the interlayer dielectric. Recent research results seem to indicate, however, that the interface formed between the copper and dielectric cap layer is a major diffusion path for material transport during operation of the metal interconnect.

Consequently, a plurality of alternatives has been developed in an attempt to enhance the interface characteristics between the copper and the cap layer having the capability of reliably confining the copper and maintaining its integrity. For example, it has been proposed to selectively provide conductive materials on top of the copper-containing region, which may exhibit superior electromigration performance while not unduly reducing the overall resistance of the corresponding metal line. For instance, a compound of cobalt/tungsten/phosphorous (CoWP) has proven to be a promising candidate for conductive cap layers, which may significantly reduce electromigration effects within a corresponding metal line.

In other examples, any other appropriate metal materials or alloys may be used to form a conductive cap layer on the exposed copper surface. These metal materials may typically be formed on the basis of electrochemical deposition recipes, such as electroless deposition, thereby requiring a high degree of selectivity of the corresponding deposition process so as to not unduly modify the characteristics of the surrounding dielectric materials. For example, a reduced degree of selectivity may result in increased leakage currents and premature dielectric breakdown of the corresponding metallization levels due to the contact with the electrolyte solution used for selectively forming the conductive cap layers on the exposed copper surface. In other cases, highly complex additional cleaning recipes may have to be applied in order to remove any contaminants created during the preceding electroless deposition of the cap material, thereby also contributing, in addition to increasing overall process complexity, to a significant surface modification of the exposed dielectric materials. Consequently, although these approaches may represent promising process techniques for providing a high electromigration resistance without unduly affecting the overall conductivity of the copper lines, significant efforts have to be made in view of providing an appropriate deposition process in combination with additional post-deposition treatments in order to maintain any significant material modifications at a low level.

In other conventional approaches, the surface condition of the exposed copper line may be modified by incorporating a silicon species into the exposed copper surface, which may result in the generation of a copper silicide material, possibly in combination with other components, such as nitrogen and the like, thereby obtaining an increased stability with respect to material diffusion. However, any such process techniques for incorporating a silicon species may require sophisticated control strategies in order to provide a desired degree of process uniformity, while at the same time the overall resistivity may increase due to the significantly reduced conductivity of the copper silicide compared to a moderately pure copper material.

In still further conventional approaches, an enhanced electromigration behavior of copper lines is accomplished by using an alloy species, such as aluminum, which may be incorporated into the copper to a certain percentage. It is well known that a certain metal species, such as aluminum, may significantly reduce the current-induced material diffusion in copper lines. For this purpose, process strategies have been developed in which the copper seed material may be applied with a corresponding percentage of, for instance, aluminum which may then be “diffused” into the copper lines after the electrochemical deposition of the bulk copper in a corresponding heat treatment. Hence, according to this approach, the aluminum species may be incorporated during the deposition of a thin copper seed layer, for instance, by sputter deposition and the like, which may thus also act as a donator for the aluminum species after the filling in of the copper material upon a heat treatment. In this way, superior electromigration behavior may be accomplished while, however, the aluminum species may be distributed across metal lines and may thus result in a reduced conductivity.

During the further device scaling, reduced dimensions may have to be provided, in particular in the lower lying metallization levels wherein a reduction of the specific conductivity of copper-based metal lines may result in increased signal propagation delay, which may not be compatible with performance requirements of advanced semiconductor devices. On the other hand, providing a metal cap layer may result in a significant increase of production costs due to a significant increase of overall process complexity.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides semiconductor devices and manufacturing techniques in which the material diffusion at a top surface of a copper-based metal line and, thus, the electromigration behavior thereof may be enhanced by locally providing an alloy-forming species at the top surface so as to enable a locally restricted alloy formation, while at the same time providing a very efficient overall manufacturing flow. For this purpose, in some illustrative aspects disclosed herein, an alloy-forming material layer may be formed on the exposed top surface of copper-based metal regions and may be subsequently treated to initiate an alloy-forming process in which the interdiffusion may thus take place at the top surface only, thereby locally restricting the presence of the alloy-forming species to the vicinity of the exposed surface area. Consequently, the top surface may exhibit superior electromigration behavior, wherein the reduction in conductivity of the copper-based metal line may be restricted to a moderately small region at the vicinity of the top surface. In some illustrative embodiments, the deposition of the alloy-forming material layer and the removal thereof may be accomplished without requiring additional masking steps, thereby achieving very efficient overall manufacturing flow.

One illustrative method disclosed herein comprises forming a metal layer on an exposed surface of a copper-containing metal region that is formed in a dielectric material of a metallization layer of a semiconductor device. The method further comprises performing a heat treatment to form an alloy at the exposed surface and removing excess material of the metal layer selectively to the exposed surface.

A further illustrative method disclosed herein relates to the formation of a metallization system of a semiconductor device. The method comprises forming an alloy-forming metal layer on a dielectric material and a surface of a copper-containing metal region of the metallization system, wherein the copper-containing metal region is laterally embedded in the dielectric material. The method further comprises performing an alloy-generating process to form an alloy on the copper-containing metal region. Additionally, the method comprises removing excess material of the alloy-forming metal layer from the surface and the dielectric material.

One illustrative semiconductor device disclosed herein comprises a metallization layer formed above a substrate and a copper-containing metal region that is laterally embedded in a dielectric material of the metallization layer, wherein the copper-containing metal region has a top surface. The semiconductor device further comprises an alloy species forming a copper alloy layer at the top surface and extending into the copper-containing metal region less than half of the thickness of the copper-containing metal region.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a semiconductor device comprising a device level with circuit elements and a metallization system including copper-based metal regions in a manufacturing stage prior to enhancing the diffusion behavior at the top surface of the metal region, according to illustrative embodiments;

FIG. 1b schematically illustrates a portion of the metallization system during a deposition process for providing an alloy-forming material layer, according to illustrative embodiments;

FIGS. 1c-1d schematically illustrate a cross-sectional view and a top view, respectively, during a treatment for initiating an interdiffusion of copper and the alloyforming species, according to illustrative embodiments;

FIG. 1e schematically illustrates a cross-sectional view of the semiconductor device during a removal process for removing the excess material of the alloy-forming layer, according to illustrative embodiments;

FIG. 1f schematically illustrates a cross-sectional view of the metal regions after the alloy formation;

FIGS. 1g-1h schematically illustrate the concentration of the alloy-forming species along the depth of the metal regions at different lateral sections for a device formed in accordance with the principles disclosed herein (FIG. 1g) and in comparison with a conventional device having the alloy species in the copper seed layer (FIG. 1h); and

FIGS. 1i-1j schematically illustrate cross-sectional views of the semiconductor device in a further advanced manufacturing stage, according to further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure addresses the problem of electromigration in copper-containing metal regions by providing an alloy-forming species in a locally restricted manner, i.e., directly on the top surface on the basis of an efficient process technique so as to incorporate the alloy-forming species in a locally restricted manner, thereby maintaining the high conductivity of the remaining portion of the copper-containing region while nevertheless providing the superior electromigration behavior at the top surface thereof. To this end, any appropriate alloy-forming species, such as aluminum and the like, may be formed, according to some illustrative embodiments, in a non-selective manner on the exposed copper surface and the dielectric material, which may be accomplished on the basis of any appropriate deposition technique. Thereafter, an alloy-generating process may be initiated, for instance, in the form of a heat treatment, wherein process parameters such as effective temperature and duration may be appropriately selected so as to adjust the degree of interdiffusion and thus of “penetration” of the copper surface by the alloy-forming species. In this manner, the finally obtained concentration of the alloy species within the copper surface may be adjusted as well as the drop of concentration towards the depth of the copper-containing metal region so that a “thickness” of the copper alloy layer may be controlled on the basis of the process parameters. Hereafter, a thickness of an alloy layer formed in a copper-containing metal region is to be understood as a region positioned at the top surface of the copper-containing metal region wherein a maximum concentration of the alloy-forming species may drop along the depth direction and wherein a bottom face of the “layer” is considered a section at which the concentration has dropped to one tenth of the maximum concentration. It should be appreciated that traces of the alloy-forming species may also be diffused into somewhat lower lying portions wherein, in some illustrative embodiments, a corresponding concentration at or beyond half the thickness of the metal region may be less than two orders of magnitude of the maximum concentration at the top surface of the metal region. In this manner, the main portion of the copper-containing metal region may exhibit its initial high conductivity, thereby not unduly deteriorating overall performance of the metallization system under consideration.

In some illustrative embodiments disclosed herein, a locally varying thickness of the alloy layer may be provided by adjusting the process parameters in a locally selective manner, for instance, by locally varying the effective temperature and/or duration of the heat treatment, thereby providing the possibility of locally selectively adapting the degree of diffusion hindering effects of the alloy layer. For instance, in device areas in which electromigration performance has been identified as being very critical, an increased thickness of the alloy layer may be provided, while, in other areas, a reduced thickness may be selected, thereby not unduly contributing to the overall resistance of the metallization system under consideration.

After forming the alloy layer in a locally restricted manner, i.e., centered at the top surface of the metal region, any excess material may be removed, for instance, by an appropriate process, such as wet chemical recipes, without requiring additional masking steps.

As a consequence, superior electromigration behavior may be obtained at the top interface of copper-containing metal regions for highly scaled semiconductor devices, for instance, in lower lying metallization layers having metal lines with a width of approximately 200 nm and less, such as 100 nm and less, wherein, however, the overall conductivity may not be unduly reduced, while at the same time a highly efficient overall manufacturing flow may be applied.

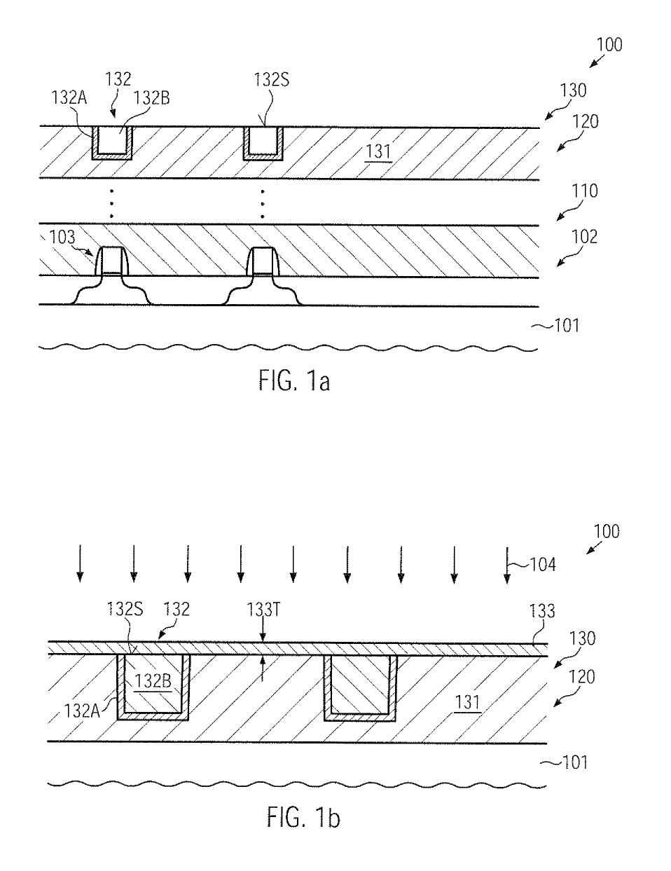

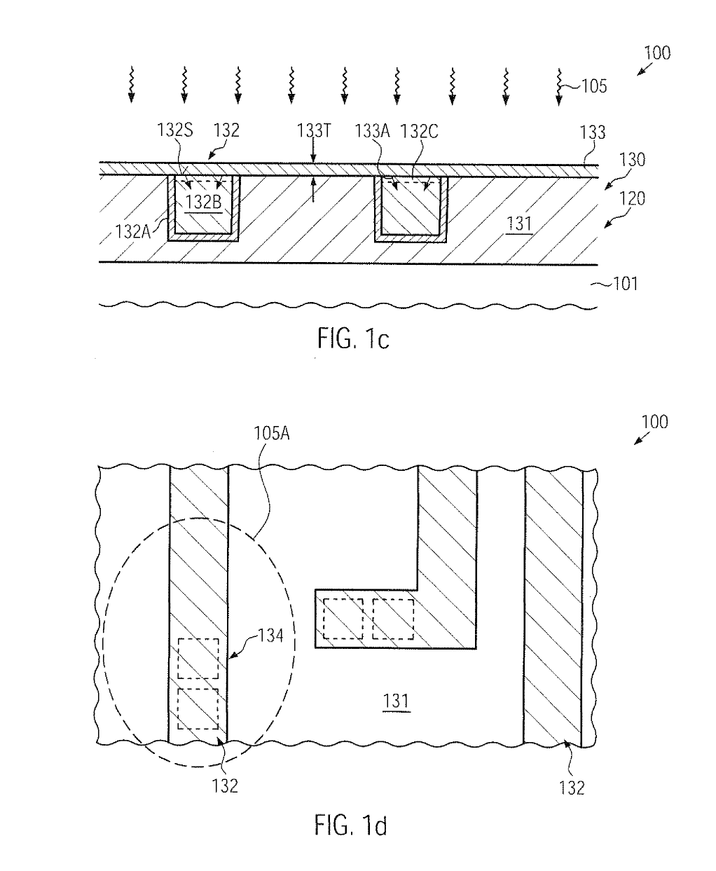

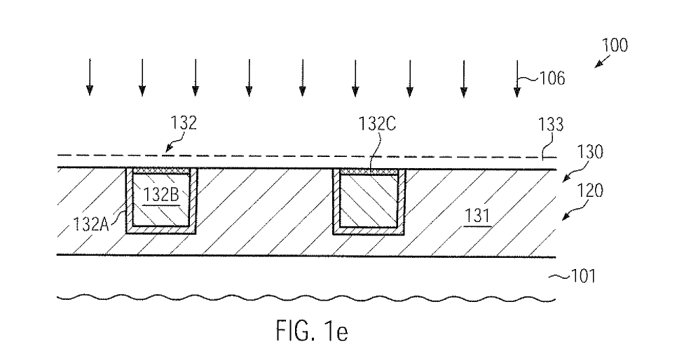

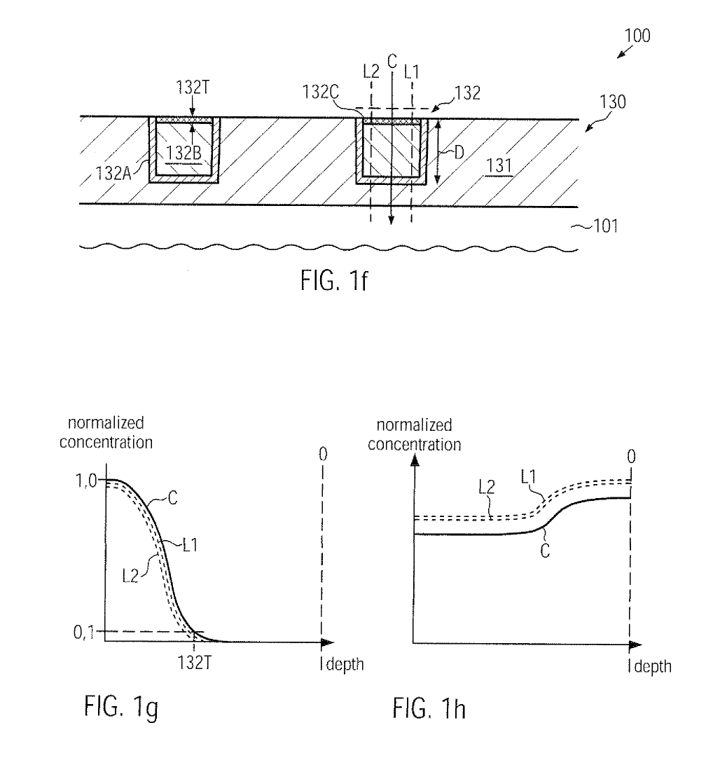

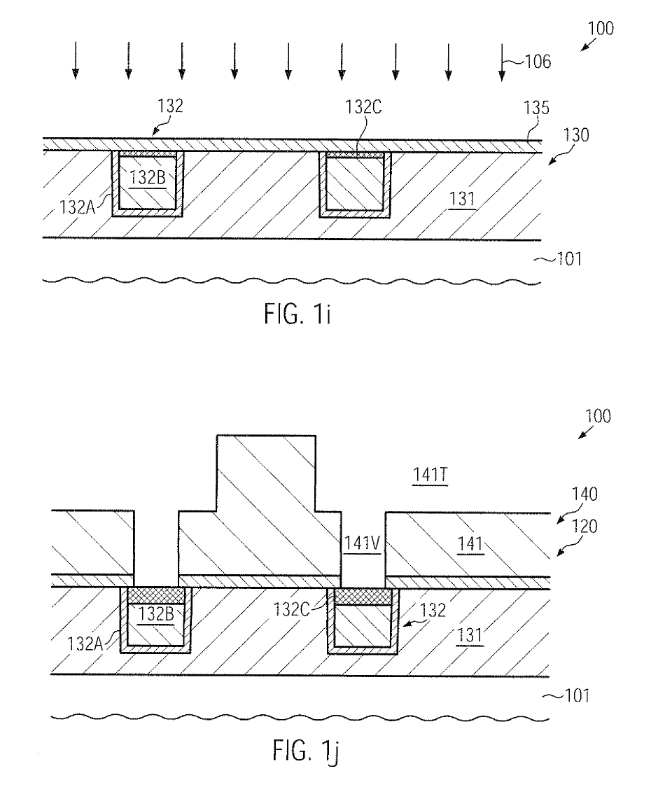

FIG. 1a schematically illustrates a cross-sectional view of a semiconductor device 100 comprising a substrate 101 above which may be formed a metallization system 120. Furthermore, in the embodiment shown, the semiconductor device 100 may comprise a device level 102, i.e., one or more material layers in and above which semiconductor-based circuit elements may be formed, such as transistors 103, resistors, capacitors and the like. The device level 102 may comprise a semiconductor material, such as a silicon-based material, or any other appropriate semiconductor material as may be required for providing the transistor elements 103 with the desired characteristics. The transistors 103 may represent transistors for analog circuitry, digital circuitry, mixed signal circuitry and the like. For example, the transistor elements 103 may be formed on the basis of design rules which may require one or more components with critical dimensions of approximately 50 nm and less. For example, many complex digital circuitry may be based on field effect transistors having a planar architecture in which one critical dimension is the length of a gate electrode, which may have a substantial influence on the overall performance of the transistor. As previously explained, by continuously reducing the size of the individual circuit elements 103, a high packing density may be achieved in the device level 102, thereby also requiring an increased packing density in the metallization system 120, which may be accomplished by providing a plurality of stacked metallization layers of which, for convenience, one metallization layer 130 is illustrated in FIG. 1a. On the other hand, in each individual metallization layer 130, reduced dimensions of corresponding metal features may be required, thereby also necessitating a superior electromigration performance, as explained above.

The semiconductor device 100 may further comprise a contact level 110, which may be considered as an interface between the metallization system 120 and the device level 102. For example, the contact level 110 may include an appropriate dielectric material for passivating the circuit elements 103, in which appropriate contact elements (not shown) may be provided so as to connect to the circuit elements 103 and to the metallization system 120. In the manufacturing stage shown in FIG. 1a, the metallization layer 130 may comprise a dielectric material 131, such as a low-k dielectric material, an ultra low-k (ULK) material, possibly in combination with “conventional” dielectric materials, such as silicon dioxide, silicon nitride, silicon carbide and the like. Furthermore, copper-containing metal regions 132 may be formed in the dielectric material 131, i.e., the metal regions 132 may be laterally embedded in the material 131, while a top surface 1325 may be exposed. In the embodiment shown, the copper-containing metal regions 132 may comprise a conductive barrier material 132A in combination with a “core” material 132B, which may be substantially comprised of copper in view of enhanced overall conductivity. That is, the core material 132B may, in some illustrative embodiments, be provided as a copper material in which a concentration of non-copper species may be approximately 0.1 atomic percent or less in order to provide high conductivity. On the other hand, the conductive barrier material 132A, which may be provided in the form of tantalum, tantalum nitride, titanium, titanium nitride, other metal alloys and the like, may provide a strong interface between the core material 132B and the dielectric material 131, thereby suppressing undue diffusion of copper into sensitive device areas and also maintaining integrity of the core material 132B.

The semiconductor device 100 as shown in FIG. 1a may be formed on the basis of the following process techniques. The circuit elements 103 in the device level 102 may be formed by well-established manufacturing techniques in accordance with the design rules of the device 100. Thereafter, the contact level 110 may be formed by depositing an appropriate dielectric material and patterning the same to receive contact openings that are subsequently filled with any appropriate metal-containing material, such as tungsten, aluminum, copper and the like, depending on the overall configuration of the device 100. Thereafter, the metallization system 120 may be formed by any appropriate manufacturing technique. For convenience, a corresponding process sequence may be described with reference to the metallization layer 130. In this case, the dielectric material 131 may be formed by appropriate deposition techniques, such as chemical vapor deposition (CVD), spin-on techniques and the like, as may be required by the material or materials under consideration. It should be appreciated that the dielectric material 131 may comprise two or more different materials, some of which may be materials having a reduced dielectric constant so as to achieve a low parasitic capacitance. Thereafter, a patterning sequence may be performed on the basis of sophisticated lithography techniques in order to form appropriate openings, in the form of lines, contact openings and the like, as may be required according to the circuit layout of the metallization layer 130. After patterning the dielectric material, i.e., after forming the appropriate trenches and openings for metal lines, vias and the like, the conductive barrier material 132A, if required, may be deposited, for instance, by physical vapor deposition (PVD), such as sputter deposition, CVD, electroless plating, atomic layer deposition (ALD) and the like. Typically, the conductive barrier material 132A may be comprised of two or more different material compositions in order to achieve the desired characteristics with respect to copper confinement, adhesion, electromigration performance and the like. Next, in some illustrative embodiments, a seed layer, such as a copper layer, may be formed, for instance, by sputter deposition, electroless deposition and the like, wherein, contrary to conventional approaches as described above, an alloy-forming species may be omitted so as to not unduly reduce overall conductivity of the core material 132B during and after the deposition thereof. In other illustrative embodiments, process techniques may be used in which the core material 132B may be directly deposited on the conductive barrier material 132A by electroless deposition techniques. During the deposition of the core material 132B, also a desired material composition, i.e., the degree of non-copper species, may be maintained at a very low level, in order to obtain a superior conductivity. Thereafter, any excess material may be removed, for instance by chemical mechanical polishing (CMP), electro CMP, electro etching and the like. Consequently, during the corresponding material removal process, the exposed surface 132S may be formed.

FIG. 1b schematically illustrates the semiconductor device 100 in a further advanced manufacturing stage wherein, for convenience, only a portion of the metallization system 120, i.e., the metallization layer 130, is illustrated. The semiconductor device 100 may be exposed to a deposition ambient 104 in which a material layer 133 may be deposited on the metallization layer 130 in order to provide an alloy-forming species for the metal regions 132. In the embodiment illustrated, the material layer 133 may be deposited in a non-selective manner, thereby providing superior process conditions compared to complex selective deposition recipes which may frequently be applied in conventional strategies when a conductive cap layer is to be formed. For example, the deposition ambient 104 may be established on the basis of physical vapor deposition recipes, CVD techniques and the like. In one illustrative embodiment, the material layer 133 may be provided in the form of an aluminum layer since aluminum may form an alloy with copper that exhibits superior electromigration behavior, as discussed above. In other illustrative embodiments, the material layer 133 may comprise, in addition to or alternatively to an aluminum species, other metal components that may result in a superior electromigration performance at the top surface 132S. For example, the layer 133 may comprise cobalt, tungsten, phosphorous and the like. In some illustrative embodiments, the layer 133 may be provided with a thickness 133T of approximately 10 nm and less, thereby providing short cycle times during the deposition process 104 and also during material removal processes in a later manufacturing stage.

FIG. 1c schematically illustrates the semiconductor device 100 during a process 105 for initiating an alloy-generating process between the layer 133 and the core material 132B. In the embodiment shown, the process 105 may be performed as a heat treatment so as to initiate interdiffusion of a species 133A and the copper of the core material 132B. The process parameters of the process 105 may be selected such that a desired penetration depth of the species 133A may be achieved and a resulting concentration may thus be obtained at the top surface 132S, thereby providing the desired diffusion behavior. Appropriate process parameters, such as temperature and duration in the case of heat treatment, may be readily established on the basis of experiments in which the dependency of one or more process parameters from the finally obtained concentration profile may be determined. For example, a temperature of approximately 300-500° C. may be applied for one to several minutes in order to initiate a corresponding interdiffusion. Consequently, during the process 105, an alloy layer or cap layer 132C may be formed at the interface 132S, wherein the characteristics, i.e., a maximum concentration and a concentration profile towards the depth direction, may be determined on the basis of the parameters of the process 105. The process 105 in the form of a heat treatment may be performed on the basis of any appropriate technique that provides the desired effective temperature of the material layer 133 and the interface 132S.

FIG. 1d schematically illustrates a top view of the device 100 according to some illustrative embodiments in which process parameters during the process 105 may be locally varied in order to locally adjust the characteristics of the resulting cap layer 132C (FIG. 1c). In FIG. 1d, it may be assumed that the material layer 133 (FIG. 1c) may be transparent such that the lines 132 and the dielectric material 131 are visible. Furthermore, the semiconductor device 100 may comprise one or more critical areas 134 in which enhanced electromigration behavior may be required, for instance, due to the provision of contact elements to a neighboring metallization layer and the like, as will be described later on in more detail. In this case, increased thickness of the cap layer 132C may be considered as advantageous and hence the process parameters at the critical area 134 may be appropriately adapted so as to obtain an increased diffusion activity during the treatment 105. In the embodiment shown in FIG. 1d, the temperature and/or the duration of the condition of increased temperature may be locally adjusted, for instance, by providing a radiation spot 105A that may be centered around the critical area 134. For example, the radiation spot 105A may be provided on the basis of a laser beam in combination with an appropriately designed scan system so that the effective temperature and the duration may be adjustable by controlling the laser beam energy, the scan system and the like. It should be appreciated that an additional absorption layer may be formed above the material layer 133, if required, when the energy absorption of the layer 133 itself may be considered insufficient for obtaining moderately low process times. Furthermore, due to the reduced thickness of the layer 133, which may be in the above-specified range, the heat conductivity may be reduced, thereby enabling a locally restricted temperature profile within the spot 105A so that a local resolution of the characteristics of the resulting cap layer may be adjustable with a similar resolution in which the spot 105A may be formed on the semiconductor device 100.

Consequently, by performing the treatment 105 (FIG. 1c) on the basis of the layer 133, a locally restricted diffusion of an alloy-forming species may be accomplished, irrespective of a further process history of the metal lines 132, for instance in view of a heat treatment that may be performed to adjust the crystallinity of the core material 132B. During a heat treatment in a previous manufacturing stage, a diffusion of an alloy species into the core material 132B may not occur, as is the case in some conventional approaches, as described above, thereby not unduly reducing the overall conductivity of the core material 132B.

FIG. 1e schematically illustrates the semiconductor device 100 when exposed to an etch ambient 106, during which excess material of the layer 133 is removed, i.e., any material that may not have been consumed in the formation of the cap layers 132C. For this purpose, in some illustrative embodiments, the etch ambient 106 may be established in the form of a wet chemical ambient, wherein a plurality of very selective etch chemicals are available for a plurality of materials. In one illustrative embodiment, the etch ambient 106 may be established on the basis of tetra methyl ammonium hydroxide (TMAH), which may exhibit a high degree of selectivity with respect to copper material, while efficiently removing aluminum. Depending on the composition of the dielectric material 131, a more or less pronounced degree of selectivity may be achieved for the material 131. It should be appreciated, however, that, due to the reduced thickness of the layer 133, the degree of material removal of layer 131 may be acceptable, even if a pronounced selectivity is not achieved during the etch process 106. Consequently, the layer 133 may be efficiently removed without requiring any masking steps, thereby providing a very efficient overall process flow.

FIG. 1f schematically illustrates the semiconductor device 100 with the cap layer 132C after the process sequence described above. Thus, the layer 132C may have a thickness in the above-defined sense to provide the desired diffusion behavior without unduly reducing the conductivity of the remaining core material 132B. As indicated, the concentration profile in the depth direction, as indicated by the arrows C, L1 an L2, may be determined for various lateral directions, i.e., for the center, indicated by C, and laterally offset positions L1, L2.

FIG. 1g schematically illustrates a typical behavior of the concentration profile along the depth direction. As indicated, the horizontal axis may represent the depth direction wherein the dashed line represents the depth or thickness of the metal region 132. The vertical axis represents the normalized concentration of the alloy-forming species, such as the aluminum species and the like, wherein the maximum concentration is used as reference value. As illustrated, curve C may represent the concentration profile in the center of the metal region 132 along the depth direction and may rapidly drop with increasing depth so that, along a significant amount of the depth of the metal region 132, substantially no alloy species may be measurable. For example, as indicated, one tenth of the maximum concentration may be considered as the thickness 132T of the alloy layer 132C. Similarly, the concentration profiles at peripheral sections L1, L2, represented by the curves L1 and L2, may have a similar shape since the diffusion of the alloy species may have its origin in the top surface so that a substantially uniform concentration profile may be obtained in the lateral direction, as indicated by curves L1 and L2.

FIG. 1h schematically illustrates a typical concentration profile for a copper metal region having the same geometry as the metal region 132 of FIG. 1f wherein, however, an alloy species may be provided in the copper seed material prior to depositing the core material, as described before. Consequently, during a corresponding heat treatment, for instance, for adjusting the crystallinity of the core material, a corresponding diffusion may take place from the sidewalls and the bottom of the metal line, thereby distributing the alloy-forming species substantially throughout the entire metal line, which may thus result in a significantly reduced conductivity.

FIG. 1i schematically illustrates the semiconductor device 100 in a further advanced manufacturing stage in which a dielectric cap layer 135 may be deposited on the dielectric material 131 and the metal regions 132. Due to the superior diffusion behavior of the metal regions 132 achieved by providing the cap layer 132C, the material 135 may be selected with respect to superior etch characteristics and reduced permittivity. Thus, any appropriate material or materials may be deposited during a process 106 so as to obtain the desired process conditions and device characteristics of the metallization layer 130.

FIG. 1j schematically illustrates the semiconductor device 100 in a further advanced manufacturing stage according to some illustrative embodiments. As illustrated, the device 100 may comprise a further metallization layer 140 in an intermediate manufacturing stage in which a dielectric material 141 of any appropriate type may be formed above the dielectric cap layer 135 and may have formed therein openings 141T and 141V, which may represent trenches and via openings for corresponding metal regions of the metallization layer 140. As illustrated, the via openings 141V may connect to the metal regions 132 at specific areas, wherein the corresponding area may be considered as a critical area with respect to overall electromigration performance or other contact related failures. Thus, as previously explained with reference to FIG. 1d, in some illustrative embodiments, the metal regions 132 may have a cap layer 132C with a locally increased thickness in order to provide enhanced device reliability with respect to the further processing and with respect to the operation of the metallization system 120. Thus, upon forming the openings 141V and subsequently depositing a conductive barrier material in combination with a seed material, if required, and the copper core material, an enhanced diffusion behavior may be achieved locally around the openings 141V due to the increased thickness of the cap layer 132C. On the other hand, a corresponding reduction in conductivity is locally restricted, depending on the spatial resolution capability of the corresponding treatment, such as the radiation spot 105A of FIG. 1d, so that the overall resistance of the metal regions 132 may not be unduly increased.

With respect to the manufacturing procedure for forming the metallization level 140 as illustrated in FIG. 1j, similar criteria may apply as previously explained with reference to the metallization layer 130.

As a result, the present disclosure provides semiconductor devices and manufacturing techniques in which an enhanced diffusion behavior at a top interface of copper-based metal regions may be accomplished by forming a copper alloy that is spatially restricted to the interface so that a high conductivity of the remaining portion of the metal region may be preserved. The incorporation of the alloy forming species may be accomplished by performing a non-masked deposition process in combination with a heat treatment or any other process for initiating the formation of an alloy, followed by a non-masked removal of a non-reacted material. Thus, a very efficient overall manufacturing sequence may be applied, thereby avoiding complex selective electrochemical deposition recipes. In some illustrative aspects, the thickness of the alloy layer may be locally adjusted on the basis of locally varying process parameters, such as effective temperature and/or duration of a corresponding heat treatment. Thus, copper-based metal lines with a width of approximately 200 nm and significantly less, as may be required in lower lying metallization levels of sophisticated semiconductor devices, may be provided on the basis of an efficient manufacturing flow while still ensuring a superior electromigration performance.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a metal layer on an exposed surface of a copper-containing metal region formed in a dielectric material of a metallization system of a semiconductor device;
performing a heat treatment so as to form an alloy at said exposed surface; and
removing excess material of said metal layer selectively to said exposed surface.

2. The method of claim 1, wherein forming said metal layer comprises depositing said metal layer on said exposed surface and said dielectric material without using a mask.

3. The method of claim 1, wherein said metal layer comprises aluminum.

4. The method of claim 3, wherein removing said excess material comprises establishing an etch ambient and removing said excess material selectively to material of said copper-containing metal region and selectively to said dielectric material.

5. The method of claim 4, wherein said etch ambient is established by using a wet etch chemistry.

6. The method of claim 5, wherein said wet etch chemistry comprises tetramethyl ammonium hydroxide (TMAH).

7. The method of claim 1, wherein said metal layer is formed with a thickness of approximately 10 nm or less.

8. The method of claim 1, wherein performing said heat treatment comprises locally adjusting a temperature during said heat treatment so as to locally adjust a concentration of material of said metal layer at said exposed surface.

9. The method of claim 1, further comprising forming a dielectric cap layer on said exposed surface including said alloy.

10. The method of claim 1, further comprising performing a second heat treatment on said copper-containing metal region so as to adjust a crystallinity of said copper-containing metal region prior to forming said metal layer.

11. A method of forming a metallization system of a semiconductor device, the method comprising:
forming an alloy-forming metal layer on a dielectric material and a surface of a copper-containing metal region of said metallization system, said copper-containing metal region being laterally embedded in said dielectric material;
performing an alloy-generating process so as to form an alloy on said copper-containing metal region; and
removing excess material of said alloy-forming metal layer from said surface and said dielectric material.

12. The method of claim 11, wherein said alloy-forming metal layer comprises aluminum.

13. The method of claim 11, wherein said alloy-forming metal layer is formed with a thickness of approximately 10 nm or less.

14. The method of claim 11, wherein performing an alloy-generating process comprises performing a heat treatment.

15. The method of claim 14, wherein an effective temperature at said surface during said heat treatment is in the range of approximately 400-600° C.

16. The method of claim 14, wherein said heat treatment is performed in a locally varying manner so as to locally adjust a concentration of said alloy at said surface.

17. The method of claim 11, wherein removing said excess material comprises performing a wet chemical etch process without using an etch mask.

18. The method of claim 17, wherein said wet chemical etch process is performed on the basis of tetra methyl ammonium hydroxide (TMAH).

19. A semiconductor device, comprising:
a metallization layer formed above a substrate;
a copper-containing metal region laterally embedded in a dielectric material of said metallization layer, said copper-containing metal region having a top surface; and
an alloy species forming a copper alloy layer at said top surface and extending into said copper-containing metal region less than half of a thickness of said copper-containing metal region.

20. The semiconductor device of claim 19, wherein said alloy species comprises an aluminum species.

21. The semiconductor device of claim 19, wherein a concentration of said alloy species decreased by at least a factor of ten at a distance of approximately 15 nm from said top surface.

22. The semiconductor device of claim 21, wherein said copper-containing metal region further comprises a conductive barrier material formed on sidewalls of said copper-containing metal region.

23. The semiconductor device of claim 19, wherein a width of said copper-containing metal region is approximately 200 nm or less.

24. The semiconductor device of claim 19, further comprising a dielectric cap layer formed on said copper alloy layer.

25. The semiconductor device of claim 19, further comprising a circuit element formed above said substrate, wherein said circuit element has a critical dimension of approximately 50 nm or less.
